(19) United States
(12) Patent Application Publication
(10) Pub. No.: US 2010/0122657 A1
(43) Pub. Date: May 20, 2010

(54) Electrode, Chemical Vapor Deposition Apparatus Including the Electrode and Method of Making

(76) Inventors: Jui Hai Hsieh, Hsinchu City (TW); Dave DeLong, Austin, TX (US)

Correspondence Address: Zarian Midgley & Johnson PLLC, University Plaza, 960 Broadway Ave., Suite 250, Boise, ID, 83706, US

(21) Appl. No.: 12/270,981

(22) Filed: Nov. 14, 2008

(51) Int. Cl. C23C 16/54; H01R 43/00; H01B 5/00

(52) U.S. Cl. 118/723 E; 29/868; 174/126.1

(57) ABSTRACT

The present disclosure is directed to a chemical vapor deposition apparatus. The apparatus comprises a chamber having a gas inlet and a gas outlet. A first electrode is at least partially positioned in the chamber. The first electrode comprises an electrically conductive first portion and an electrically conductive second portion, the first portion being attached to the second portion by a first TIG weld bead. A second electrode is at least partially positioned in the chamber. The second electrode comprises an electrically conductive third portion and an electrically conductive fourth portion, the third portion being attached to the fourth portion by a second TIG weld bead. An electrode and a method of making the electrode are also disclosed.

### BACKGROUND

1. Field of the Disclosure

The present disclosure relates generally to electrodes, such as electrodes employed in CVD reactors, and in particular, to electrodes made using tungsten inert gas (TIG) welding.

2. Description of the Related Art

A popular method of manufacturing high purity polycrystalline silicon is through the use of a CVD reactor. An example of a CVD reactor employed in such methods is known as a “Siemens Reactor”. As is well known in the art, such reactors include a deposition chamber having a gas inlet and gas outlet for maintaining the flow of source gas into and out of the reactor. During the manufacture of silicon in CVD reactors, a CVD reaction takes place on silicon rods which are heated to high temperatures, such as, for example, temperatures of about 1100° C. or more. The heat up is accomplished via electrical power introduced into the chamber through vertical stand electrodes which conduct electrical current and heat up the silicon rods. The rods are exposed to a reaction gas which is typically a mixture of hydrogen and a silicon source gas. A common silicon source for this application is trichlorosilane (TCS). Other well known source gases include monosilane and triethoxysilane.

In order to conduct high levels of power into the CVD reactor chamber, an electrode made of copper, such as oxygen-free copper, is often used. FIG. 1 illustrates an example of such an electrode 10. As is well known in the art, a plurality of such electrodes, such as 24 to 48 electrodes, can be at least partially positioned in the CVD reaction chamber. The relatively complex design of this electrode 10 provides for conductance of high electrical current, acceptance of high voltage contacts, as well as adequate cooling water flow. A polymer insulating material, such as PTFE, is often employed on the outside of the electrode. The insulation material works as electrical isolation, as well as an air-tight seal. Water cooling of the electrode is achieved through, for example, a cavity 12 in the body of the electrode, using a pipe 14 to guide the cooling water from the water inlet 16 to the top of the electrode body, and then flowing to the outlet 18 on the opposite side of the electrode body. The water pressure is sufficiently high to achieve enough water flow to keep the electrode temperature from melting the polymer insulating materials and the copper itself. The pipe through which the water flows can be enclosed in the electrode cavity using a base cap.

A manufacturing process employing copper brazing is often used to join the electrode body 20 with the base cap 22. The resulting joint 24 is inherently a weak link with high susceptibility to water leaks, which causes a low yield in the copper brazing manufacturing process and drives up the overall cost of the electrode. The joint is also susceptible to developing water leaks during silicon manufacture, which shortens the lifetime of the electrode and causes an increase in unscheduled maintenance downtime and loss of production time for CVD reactor.

The brazing process employs a filler metal that is chosen so as to melt at a desired brazing temperature. Examples of filler materials often used in copper brazing include copper silver alloys, including copper silver that is alloyed with other metals, such as Zn, Cd, P, Ni or Sn. In a copper silver alloy, the ratio of copper to silver can range from about 1:10 to about 85:100.

Another disadvantage of the brazing processes is that it can heat up the entire electrode, or a substantial portion thereof, to a relatively high temperature of 850° C. or greater. This can result in undesirable deformation of the electrode shape during the brazing process. Further, mistakes in brazing can be difficult to correct if defects are found. This is because in order to correct the defects, all or substantially all of the brazing filler is removed, and then the brazing process is repeated.

The present disclosure is directed to overcoming, or at least reducing the effects of, one or more of the issues set forth above.

### SUMMARY

An embodiment of the present disclosure is directed to a chemical vapor deposition apparatus. The apparatus comprise a chamber having a gas inlet and a gas outlet. A first electrode is at least partially positioned in the chamber. The first electrode comprises an electrically conductive first portion and an electrically conductive second portion, the first portion being attached to the second portion by a first TIG weld bead. A second electrode is at least partially positioned in the chamber. The second electrode comprises an electrically conductive third portion and an electrically conductive fourth portion, the third portion being attached to the fourth portion by a second TIG weld bead.

Another embodiment of the present disclosure is directed to an electrode. The electrode comprises an electrically conductive first portion and an electrically conductive second portion. The first portion is attached to the second portion by a TIG weld bead.

Yet another embodiment of the present disclosure is directed to a method of forming a first electrode. The method comprises welding an electrically conductive first portion to an electrically conductive second portion. The welding of the first portion and the second portion is accomplished by a first welding process.

### BRIEF DESCRIPTION OF THE DRAWINGS

FIG. 1 illustrates a prior art CVD electrode.

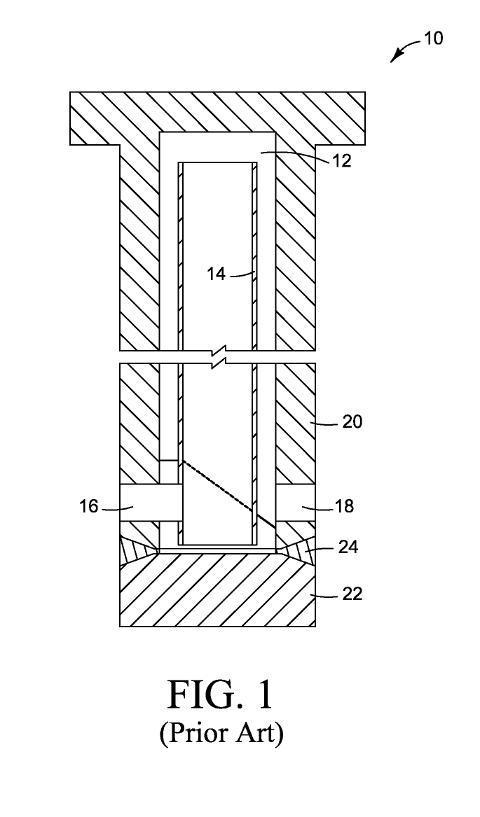

FIG. 2 illustrates a schematic drawing of a CVD apparatus, according to an embodiment of the present disclosure.

FIG. 3 illustrates an electrode employed in the CVD apparatus of FIG. 2, according to an embodiment of the present disclosure.

FIG. 4 illustrates a method of manufacturing a chemical vapor deposition apparatus, according to an embodiment of the present disclosure.

While the disclosure is susceptible to various modifications and alternative forms, specific embodiments have been shown by way of example in the drawings and will be described in detail herein. However, it should be understood that the disclosure is not intended to be limited to the particular forms disclosed. Rather, the intention is to cover all modifications, equivalents and alternatives falling within the spirit and scope of the invention as defined by the appended claims.

### DETAILED DESCRIPTION

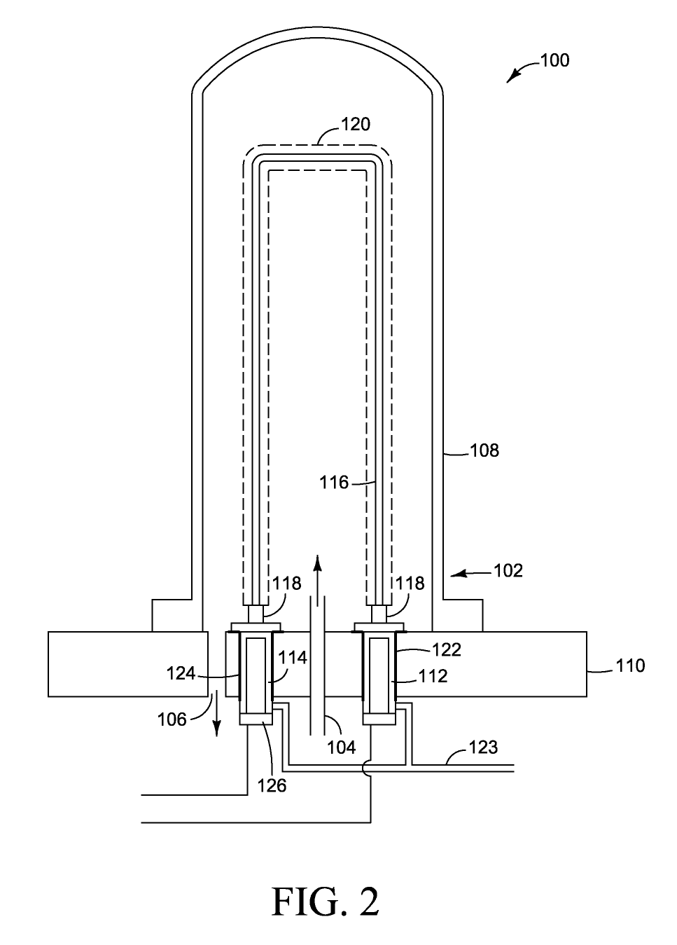

FIG. 2 illustrates a chemical vapor deposition (“CVD”) apparatus 100, according to an embodiment of the present disclosure. Chemical vapor deposition apparatus 100 can comprise a chamber 102, including a gas inlet 104 and a gas outlet 106. Chamber 102 can have any shape or size that is suitable for chemical vapor deposition. In an embodiment, chamber 102 can comprise a bell jar 108 and a chamber wall 110. In an embodiment, both the bell jar 108 and the chamber wall 110 can be water cooled to minimize deposition on these chamber surfaces.

CVD apparatus 100 can comprise a plurality of electrodes 112 and 114 which are suitable for conducting relatively high levels of power into the CVD reactor. For example, the chamber can include 2 or more electrodes 112 and 114, such as, for example, 24 to 48 electrodes. Electrodes 112 and 114 can be at least partially positioned in the chamber 102. For example, electrodes 112 and 114 can be positioned to extend through the chamber wall 110, as illustrated in FIG. 2. In an embodiment, the electrodes can be identical. In other embodiments, the electrodes can be different, such as having different shapes, sizes or being made of different materials.

During operation of the CVD apparatus 100, electrodes 112 and 114 are electrically connected to form a closed loop of electrical current. For example, electrodes 112 and 114 can be coupled to a silicon rod 116 via graphite adaptors 118, as is well known in the art. For example, silicon rod 116 can be positioned in the chamber so that a first end of the silicon rod 116 is coupled to the electrode 112 and a second end of the silicon rod 116 is coupled to the electrode 114.

Electrodes 112 and 114 can be connected to a high voltage power source (not shown) that provides sufficient power to heat silicon rod 116 to a desired temperature range for depositing silicon 120 onto the rod 116. The high voltage power source can be chosen to provide any suitable amount of power, depending on the number of rods in the chamber, the growth rate, cooling efficiency of the chamber wall, and other factors. For example, the power supplied by the power source can range from about 6000 KVA to about 20,000 KVA. The power is sufficient to provide an electrical current from one electrode to another via the silicon rod 116, thereby heating silicon rod 116 to a desired deposition temperature.

The deposition temperature can be chosen to be any suitable temperature based on a number of factors, such as the silicon source gas to be employed and the desired growth rate. Examples of suitable deposition temperatures can range from about 750° C. to about 1250° C., or higher. In an embodiment, the temperature can range from about 1000° C. to about 1200° C., such as about 1100° C.

An insulating material 122 can be employed to electrically insulate the electrodes 112 and 114 from the chamber wall 110, as is well known in the art. Examples of suitable insulating materials can include polymers, such as PTFE.

In order to avoid certain problems, such as melting of the insulating material 122, the electrodes can be cooled by flowing a coolant through the electrodes 112 and 114. Any suitable coolant can be employed, such as, for example, DI water. The coolant can be supplied in any suitable means, such as, for example, through supply pipes 123.

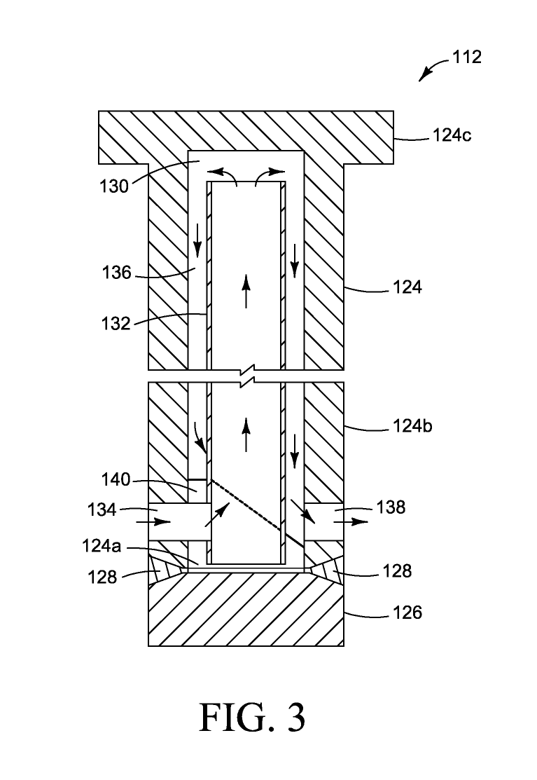

Electrodes 112 and 114 comprise an electrically conductive first electrode portion 124 and an electrically conductive second electrode portion 126. As is more clearly illustrated in FIG. 3, first electrode portion 124 is coupled to second electrode portion 126 by a tungsten inert gas (“TIG”) weld 128.

In an embodiment, a cavity 130 extends longitudinally partway through the first portion 124 of electrode 112. A conduit 132 can be positioned in the cavity 130 through an opening 124a. The second electrode portion 126 can be positioned to cover opening 124a and enclose conduit 132 inside the cavity 130.

Conduit 132 can be configured so as to be capable of being positioned inside cavity 130 in a manner that provides for fluid flow of a coolant through the electrode 112. For example, as illustrated in FIG. 3, coolant can enter the electrode 112 through inlet 134 and flow through the conduit 132. After exiting conduit 132, the fluid can flow through an annular passage 136 that is formed between conduit 132 and the electrode portion 124, before exiting the electrode 112 through outlet 138.

The first and second electrode portions 124 and 126 can comprise any suitable conductive material that can provide an electrical conductivity of about 100% IACS or greater and that can withstand the operating conditions to which the electrode will be subjected, which may include relatively high operating temperatures and stresses due to high pressure coolant flows. In an embodiment, the high conductivity metal can comprise at least 99% pure copper by weight, such as 99.95% pure copper. In an embodiment, the conductive material can be chosen from metals having a low oxygen content, such as a metal comprising an oxygen content of 0.05% or less, such as an oxygen content ranging from about 0 to about 0.035%, or about 0 to about 0.001%. Examples of suitable low oxygen content metals include low oxygen content copper, such as substantially oxygen free copper (“OFC”) or an alloy thereof. For purposes of this specification, “substantially oxygen free copper” is defined to be 99.95% pure copper having 0.001% or less of oxygen content with the minimum conductivity of 100% IACS. Thus, such substantially oxygen free copper has the benefit of being highly conductive. In another embodiment, electrolytic tough pitch copper (ETP Cu) may be employed, which can have an oxygen content ranging from about 0.02% to about 0.035% by weight (200-350 ppm).

The first and second electrode portions 124 and 126 can be any suitable shape that results in the desired electrode configuration when they are coupled together. In an embodiment, the first electrode portion 124 of electrode 112 has a cylindrical shaped electrode portion 124b through which cavity 130 at least partially extends. A lip 124c can extend out from cylindrical electrode portion 124b at one end of electrode 112. Lip 124 can be designed to aid in supporting the weight of electrode 112 in the chamber wall 110, as seen from FIG. 2.

In an embodiment, the weld 128 coupling first electrode portion 124 to second electrode portion 126, as illustrated in FIG. 3, can be formed using any suitable tungsten inert gas welding process. For example, the ends of the first electrode portion 124 and second electrode portion 126 can be tapered so that when they are positioned together for welding, a “V” shaped trench is formed between them.

Prior to welding, the area of the electrode to be welded can be conditioned by various optional cleaning processes. For example, after the electrode portions are tapered, they can be degreased using a surfactant; rinsed with water to remove the surfactant; washed with an acid to remove residues, oxides, and/or other contaminants on the metal surface, rinsed to remove the acid and then dried.

The electrode portions can then optionally be pre-heated to a desired temperature prior to welding. The pre-heat is performed because the high heat conductivity of the copper electrode portions can conduct heat away from the welding zone relatively quickly. This can cause the welding zone to have insufficient heat to fully melt the filing materials or to form the desired metallic bond to the parent materials. Pre-heating the parent materials prior to welding can smooth out the thermal step to effectively slow the heat flow from the welding area to the electrode portions, thereby allowing the heat generated by the welding to sufficiently melt the filler material. Any suitable pre-heating temperature can be employed. Examples of suitable pre-heat temperatures range from about 150° C., or about 200° C., or higher.

After preheating, a tungsten metal tip commonly employed in TIG welding can then be used to perform the welding process. In an embodiment, the tungsten metal tip is used to generate a plasma to produce sufficient heat to melt a filler material so that it flows and fills the trench, which results in the substantially “V” shaped weld 128 of the embodiment of FIG. 3.

In an embodiment, the tungsten inert gas weld is formed using a filler material 128. Any suitable metal or metal alloy that will provide a desired conductivity can be employed as a metal filler. Examples of suitable metal filler materials include high conductivity coppers, such as oxygen free copper, OFC alloys, silver and silver alloys. In another embodiment, the metal filler comprises electrolytic tough pitch copper (ETP Cu), which can have an oxygen content ranging from about 0.02% to about 0.035% by weight (200-350 ppm), or an alloy thereof.

In an embodiment, the alloy can include a base metal, such as OFC, silver or ETP Cu and one or more additives. The additives can enhance the performance of the metal filler, such as by providing for reduced oxidation of the metal during welding or providing improved bonding of the metal filler to the parent metals. Examples of suitable additives can include Sn, Mn, Si, P, Al, Pb and mixtures thereof; such as mixtures of 2, 3, 4, 5 or all 6 of these additives. Still other metal additives are well known in the art, including additives such as silver. Any suitable additive can be employed.

Any suitable concentrations of additives can also be employed. In an embodiment, the additives comprise 5% or less of the metal filler by weight. For example, a base metal can be at least 95% of the metal filler by weight, such as about 97 to about 99.99% and the concentrations of the additives can be about 5% or less, such as about 0.01% to about 3% by weight. As with other ranges set forth herein, these ranges are exemplary only. Accordingly, concentrations outside of these ranges can also be employed.

The filler metal can have a relatively low oxygen content, such as a metal comprising an oxygen content of 0.1% or less by weight, such as a content ranging from about 0 to about 0.05%, or about 0 to about 0.001% (i.e., 10 ppm or less), by weight. In an embodiment, the filler material comprises substantially oxygen free copper (“OFC”), as defined above, or an alloy thereof.

Examples of suitable conductivities for the resulting weld bead range from about 80% to about 100% IACS or greater, such as about 90% to about 95% IACS. The weld bead can include metals similar to those discussed above for the filler materials and in similar concentrations. However, one of ordinary skill in the art would readily understand that the concentrations of ingredients in the weld bead may not be identical to those in the metal filler due to, for example, the vaporization of some ingredients during the welding process. In an embodiment, the weld bead can comprise a base metal in a concentration of at least 95% of the weld bead by weight, such as about 97 to about 99.99% and the concentrations of the additives are about 5% or less, such as about 0.01% to about 3% by weight.

An inert gas is employed during the TIG welding process, as is well known in the art. Any suitable inert gas can be used, such as argon or helium. The inert gas substantially reduces contaminants, such as oxygen, in the weld area, which could oxidize the filler and thereby degrade the weld. For example, oxidation of the filler material could decrease electrical conductivity of the weld 128.

Following the welding, an optional cleaning process can be performed. For example, the electrode can be degreased using a surfactant; rinsed with water to remove the surfactant; washed with an acid to remove residues, oxides, and/or other contaminants on the metal surface, rinsed to remove the acid and then dried.

Thus, the present disclosure is directed to a method of forming a first electrode comprising welding an electrically conductive first portion to an electrically conductive second portion. The welding of the first portion and the second portion are accomplished by a first TIG welding process, as described above.

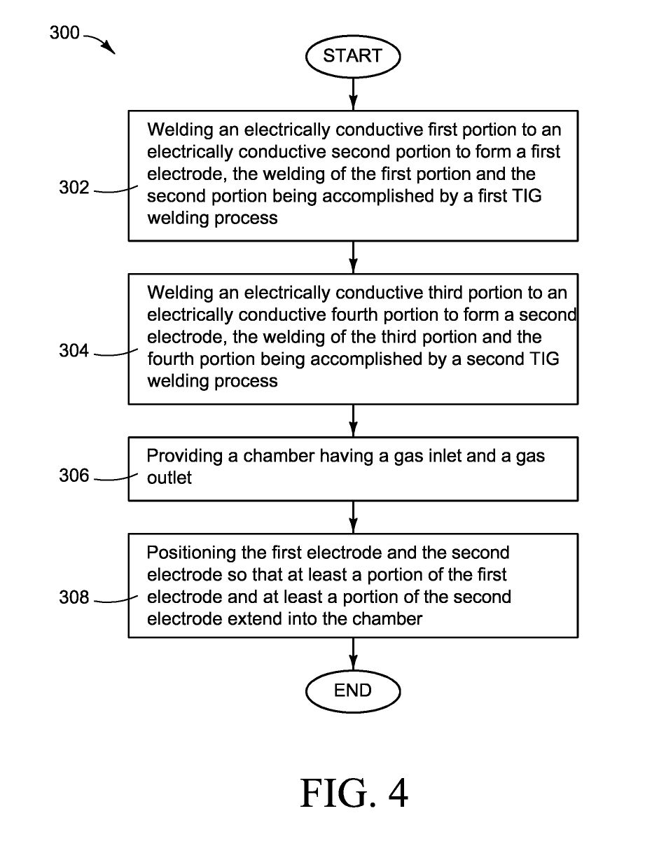

FIG. 4 shows a method of manufacturing a chemical vapor deposition apparatus using a TIG welding process, according to an embodiment of the present disclosure. The method comprises welding an electrically conductive first portion to an electrically conductive second portion to form a first electrode. The welding of the first portion and the second portion is accomplished by a first TIG welding process, as illustrated at 302 of FIG. 4. A second electrode can be formed by welding an electrically conductive third portion to an electrically conductive fourth portion by a second TIG welding process, as described at 304. A chamber having a gas inlet and a gas outlet is provided. The first electrode and the second electrode are positioned so that at least a portion of the first electrode and at least a portion of the second electrode extend into the chamber, as described at 308.

Defects in the weld bead formed by the TIG welding process can often be corrected without having to remove all or substantially all of the weld bead. For example in an embodiment, the TIG welding process employed to form the electrodes of the present disclosure can be an automated process. Automated TIG welding processes are generally well known. Following the TIG welding process, the weld bead can be inspected for defects. If defects are found, the weld bead can be reworked to correct the process using a second welding process. For example, a second TIG welding process can be manually performed to correct the defects. Alternatively, the second TIG welding process can be performed using automated techniques.

Welding electrodes with a TIG welding process may provide one or more advantages over a conventional brazing process, including at least one of: increased electrical conductivity, increased heat conductance, improved tensile (mechanical) strength, improved chemical resistance, lower manufacturing cost by improved manufacturing yield, longer electrode lifetime, lower cost of operation for reactors and/or reduced deformation of the parent materials.

Although various embodiments have been shown and described, the disclosure is not so limited and will be understood to include all such modifications and variations as would be apparent to one skilled in the art.

What is claimed is:

1. A chemical vapor deposition apparatus, comprising:
a chamber having a gas inlet and a gas outlet;
a first electrode at least partially positioned in the chamber, the first electrode comprising an electrically conductive first portion and an electrically conductive second portion, the first portion being attached to the second portion by a first TIG weld bead; and
a second electrode at least partially positioned in the chamber, the second electrode comprising an electrically conductive third portion and an electrically conductive fourth portion, the third portion being attached to the fourth portion by a second TIG weld bead.

2. The chemical vapor deposition apparatus of claim 1, wherein the first TIG weld bead and the second TIG weld bead have a conductivity of about 80% IACS or greater.

3. The chemical vapor deposition apparatus of claim 1, wherein the first TIG weld bead and the second TIG weld bead comprise a metal chosen from OFC, OFC alloy, ETP Cu, ETP Cu alloy, silver and silver alloy.

4. The chemical vapor deposition apparatus of claim 3, wherein the first TIG weld bead and the second TIG weld bead are at least 95% oxygen free copper.

5. The chemical vapor deposition apparatus of claim 4, wherein the electrically conductive first portion and the electrically conductive second portion both comprise substantially oxygen free copper.

6. The chemical vapor deposition apparatus of claim 1, further comprising a silicon rod positioned in the chamber, a first end of the silicon rod being coupled to the first electrode and a second end of the silicon rod being coupled to the second electrode.

7. The chemical vapor deposition apparatus of claim 1, further comprising
a third electrode at least partially positioned in the chamber, the third electrode comprising an electrically conductive fifth portion and an electrically conductive sixth portion, the fifth portion being attached to the sixth portion by a third TIG weld bead; and
a fourth electrode at least partially positioned in the chamber, the fourth electrode comprising an electrically conductive seventh portion and an electrically conductive eighth portion, the seventh portion being attached to the eighth portion by a fourth TIG weld bead.

8. An electrode comprising an electrically conductive first portion and an electrically conductive second portion, the first portion being attached to the second portion by a TIG weld bead.

9. The electrode of claim 8, wherein the conductive first portion comprises a first end and a second end, a cavity extending longitudinally through the conductive portion from the first end partially through the electrode, an inlet and an outlet; and wherein the conductive second portion comprises a conductive end portion attached to the first end of the conductive first portion by the weld bead; and
further comprising a conduit positioned in the cavity, the conductive first portion and the conduit configured so that a coolant can flow into the electrode through the inlet and out of the electrode through the outlet.

10. The electrode of claim 8, wherein the weld bead has a conductivity of about 80% IACS or greater.

11. The electrode of claim 8, wherein the weld bead comprises a metal chosen from OFC, OFC alloy, ETP Cu, ETP Cu alloy, silver and silver alloy.

12. The electrode of claim 11, wherein the weld bead is at least 95% oxygen free copper.

13. The electrode of claim 12, wherein the electrically conductive first portion and the electrically conductive second portion both comprise substantially oxygen free copper.

14. The electrode of claim 8, wherein the electrically conductive first portion and the electrically conductive second portion both comprise at least 99% pure copper by weight.

15. A method of forming a first electrode comprising welding an electrically conductive first portion to an electrically conductive second portion, the welding of the first portion and the second portion being accomplished by a first welding process.

16. The method of claim 15, wherein the TIG welding process is carried out using a filler material chosen from substantially oxygen free copper and alloys thereof.

17. The method of claim 15, wherein the TIG welding process is carried out using a filler material chosen from OFC, OFC alloy, ETP Cu, ETP Cu alloy, silver and silver alloy

18. The method of claim 15, wherein the electrically conductive first portion and the electrically conductive second portion comprise 99% pure copper by weight.

19. The method of claim 15, wherein the TIG welding process is automated, the method further comprising detecting one or more defects in a weld bead formed by the TIG welding process, and reworking the weld bead to correct the defects.
